(19) United States
(12) Patent Application Publication
(10) Pub. No.: US 2006/0279358 A1
(43) Pub. Date: Dec. 14, 2006

(54) Electronic device and method for manufacturing linear antenna thereof

(76) Inventors: Arthur Chang, Taipei (TW); Chi-Cheng Liao, Taipei (TW)

Correspondence Address: RABIN & Berdo, PC, 1101 14TH STREET, NW, SUITE 500, WASHINGTON, DC, 20005, US

(21) Appl. No.: 11/449,698

(22) Filed: Jun. 9, 2006

(30) Foreign Application Priority Data
Jun. 10, 2005 (TW) 94119410

(51) Int. Cl. H03F 3/26

(52) U.S. Cl. 330/262

(57) ABSTRACT

An electronic device and a method for manufacturing a linear antenna thereof are provided. The electronic device includes a casing, several guiding bosses, a circuit board and a linear antenna. The casing has an inner wall. The guiding bosses are disposed on the inner wall. The circuit board is disposed inside the casing. The linear antenna is arranged around part of the guiding bosses along a path. The linear antenna is electrically connected to the circuit board and a receiver respectively.

This application claims the benefit of Taiwan application Serial No. 94119410, filed Jun. 10, 2005, the subject matter of which is incorporated herein by reference.

### BACKGROUND OF THE INVENTION

1. Field of the Invention

The invention relates in general to an electronic device, and more particularly to an electronic device and method for manufacturing a linear antenna thereof.

2. Description of the Related Art

As the technology changes with each passing day, the portable electronic devices, especially the mobile phones, have become the necessary parts of modern lives. Because the mobile phones have the properties of light weight and small size, people can easily use the mobile phones to communicate with each other anywhere and anytime.

In the conventional mobile phone, the antenna can be a protrusive antenna or a hidden antenna. The conventional hidden antenna is an antenna module. The conventional antenna module is an electrically conductive thin metal film, such as brass or galvanized iron. The electrically conductive thin metal film is disposed inside the casing of the mobile phone and is electrically connected to a printed circuit board (PCB) and a receiver, for receiving and transmitting signals.

However, the conventional antenna module has to be made by a mold, and the performance of the antenna module must be tested. When the conventional antenna module dose not pass the performance test, a new mold has to be made to manufacture a different antenna module. As a result, the cost is increased due to manufacturing the new mold, and the manufacturing time of the antenna is increased as well.

Furthermore, because the conventional antenna module is disposed in parallel with the PCB, the area of the conventional antenna module must be 20 mm by 40 mm at least. Accordingly, the conventional antenna module considerably occupies the inner space of the mobile phone. Moreover, electronic components can not be disposed near the conventional antenna module, for preventing interfering with the performance of the antenna module in receiving and transmitting signals. Therefore, the utilization of the inner space in the conventional mobile phone is limited enormously, and the size of the mobile phone is increased.

Other electronic devices utilizing antenna modules, such as a personal digital assistant (PDA) or an electronic device utilizing a global positioning system (GPS), also face the above-mentioned problems as well.

### SUMMARY OF THE INVENTION

It is therefore an object of the invention to provide an electronic device and method for manufacturing a linear antenna thereof. The problem that the conventional antenna module needs to be remolded due to poor performance can be solved. Therefore, the cost of the mold is decreased, and the time for manufacturing the antenna is shortened. Furthermore, the linear antenna of the invention can reduce the space it occupies in the electronic device, in order to release more space for receiving other electronic components.

The embodiment of the invention achieves the above-identified objects by providing an electronic device including a casing, several guiding bosses, a circuit board, a receiver and a linear antenna. The casing has an inner wall. The guiding bosses are disposed on the inner wall. The circuit board is disposed inside the casing. The linear antenna is arranged around the guiding bosses along a path. The linear antenna is electrically connected to the circuit board and a receiver respectively.

The embodiment of the invention achieves the above-identified objects by providing a method for manufacturing a linear antenna of an electronic device. First, a back cover having an inner wall is provided. Then, several guiding bosses are formed on the inner wall. Afterwards, a linear antenna is arranged around part of the guiding bosses along a path. Next, the linear antenna is electrically connected to a circuit board and a receiver respectively. Subsequently, the performance of the linear antenna in receiving and transmitting signals is tested.

Accordingly, the utilization of the inner space in the embodiment of the electronic device is improved enormously. So that the space that the linear antenna of the invention occupies is much less than the space that the conventional antenna module does, and the appearance of the electronic device utilizing the linear antenna of the invention can easily be designed.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 illustrates part of an inner structure of an electronic device according to the first embodiment of the invention;

FIG. 2 illustrates part of the electronic device in FIG. 1 when different linear antennas formed by different metal wires arranged along different paths;

FIG. 3 illustrates part of the electronic device in FIG. 1 when the guiding bosses which the first metal wires are not arranged around are removed;

FIG. 4 illustrates part of the electronic device in FIG. 1 when a front cover and a back cover are connected together;

FIG. 5 illustrates a flow chart of a method for manufacturing a linear antenna of an electronic device according to the second embodiment of the invention;

FIG. 6A˜6B illustrate two flow charts after step 55 in FIG. 5 when the first linear antenna passes the performance test;

FIG. 7 illustrates a flow chart after step 55 in FIG. 5 when the first linear antenna does not pass the performance test;

FIG. 8A˜8B illustrate two flow charts after step 74 in FIG. 7 when the second linear antenna passes the performance test; and

FIG. 9 illustrates a flow chart after step 74 in FIG. 7 when the second linear antenna does not pass the performance test.

### DETAILED DESCRIPTION OF THE INVENTION

First Embodiment

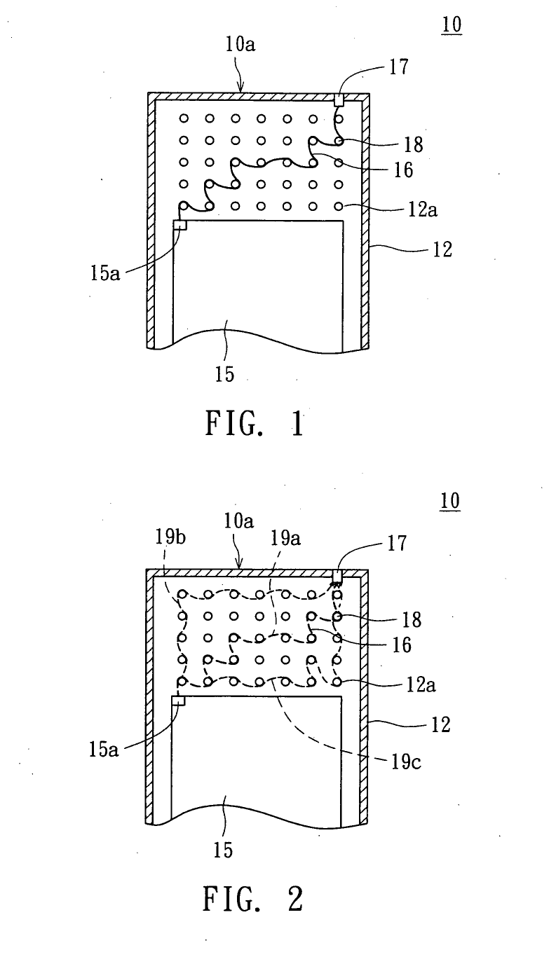

Please referring to FIG. 1, part of an inner structure of an electronic device according to the first embodiment of the invention is illustrated. In FIG. 1, the electronic device 10 includes a casing 10a, several guiding bosses 18, a circuit board 15 and a first linear antenna 16. The casing 10a has an inner wall 12a. The guiding bosses 18 are disposed on the inner wall 12a. The circuit board 15 is disposed inside the casing 10a. As shown in FIG. 2, the first antenna 16 is arranged around part of the guiding bosses 18 along a first path 19a. Two ends of the first linear antenna 16 are used for electrically connecting to the circuit board 15 and a receiver 17 respectively.

In FIG. 2, the first path 19a, a second path 19b and a third path 19c are illustrated. According to the present embodiment of the invention, different antennas can easily be formed on the inner wall 12a along different paths. For example, the first linear antenna 16 is formed by being arranged around part of the guiding bosses 18 along the first path 19a, and different linear antennas can be formed by being arranged around part of the guiding bosses 18 along the second path 19b or the third path 19c. And then, the performance of the antennas in receiving and transmitting signals is tested, for obtaining the linear antenna with the better performance in receiving and transmitting signals. As to the manufacture of the first linear antenna 16 is referred in the following paragraph.

In the present embodiment of the invention, the casing 10a includes a back cover 12 having the inner wall 12a. Therefore, the guiding bosses 18 are separately disposed on the inner wall 12a of the back cover 12. Furthermore, the guiding bosses 18 are disposed on the inner wall 12a in a regular arrangement or an irregular arrangement. For example, the guiding bosses 18 are disposed on the inner wall 12a regularly in an array. Moreover, the circuit board 15 has an electronic terminal 15a. The receiver 17 is disposed on a sidewall of the casing 10, such as a sidewall of the back cover 12. The two ends of the first linear antenna 16 are electrically connected to the electronic terminal 15a of the circuit board 15 and the receiver 17 respectively.

In the process of manufacturing the first linear antenna 16, metal wires in different lengths must be arranged around the guiding bosses 18 along different paths to form the corresponding linear antennas. When each linear antenna is formed, the linear antenna, the circuit board 15 and the receiver 17 are electrically connected to test the performance of the linear antenna in receiving and transmitting signals. By repeatedly arranging different metal wires around the guiding bosses along different paths to form different linear antennas and then testing the performance of different linear antennas in receiving and transmitting signals, the first linear antenna with better performance in receiving and transmitting signals can be obtained.

The method for obtaining the first linear antenna 16 with better performance in receiving and transmitting signals is illustrated briefly as follow.

As shown in FIG. 2, a second linear antenna is formed by arranging a metal wire around part of the guiding bosses 18 along the second path 19b. Then, the performance of the second linear antenna in receiving and transmitting signals is tested, and then the performance is tested to be poor. Therefore, the second linear antenna does not pass the performance test. And the metal wire is separated from the guiding bosses 18.

Afterwards, a third linear antenna is formed by arranging a metal wire around part of the guiding bosses 18 along the third path 19c. The performance of the third linear antenna in receiving and transmitting signals is tested, and then the performance is tested to be poor, too. Therefore, the third linear antenna does not pass the performance test. Then, the metal wire is separated from the guiding bosses 18. The guiding bosses 18 which the third linear antenna is arranged around and those which the second linear antenna is arranged around are not all the same.

Then, the first linear antenna 16 in FIG. 1 is formed by arranging a metal wire around part of the guiding bosses 18 along the first path 19a. The performance of the first linear antenna in receiving and transmitting signals is tested and is better. Therefore, the arrangement of the linear antenna is completed. The guiding bosses 18 which the first linear antenna 16 is arranged around and those which the second linear antenna is arranged around are not all the same. The guiding bosses 18 which the first linear antenna 16 is arranged around and those which the third linear antenna is arranged around are not all the same. Furthermore, because the arrangements of the first path 19a, the second path 19b and the third path 19c on the inner wall 12a are different, the arrangements of the first linear antenna 16, the second antenna and the third antenna are different.

The length of the metal wire is adjusted according to the lengths of the first path 19a, the second path 19b and the third path 19c. When the lengths of the first path 19a, the second path 19b and the third path 19c are the same, the same metal wire can be used. When the lengths of the first path 19a, the second path 19b and the third path 19c are different, different metal wires in different lengths are used.

Therefore, the design of the present embodiment that several guiding bosses 18 are disposed in the casing 10 enables different linear antennas to be formed by different metal wires arranged around the guiding bosses 18 in different lengths along different paths. And the performance of different linear antennas in receiving and transmitting signals can be tested to obtain at least one linear antenna with better performance in receiving and transmitting signals. As a result, the arrangement of the linear antennas in other electronic devices can be processed accordingly.

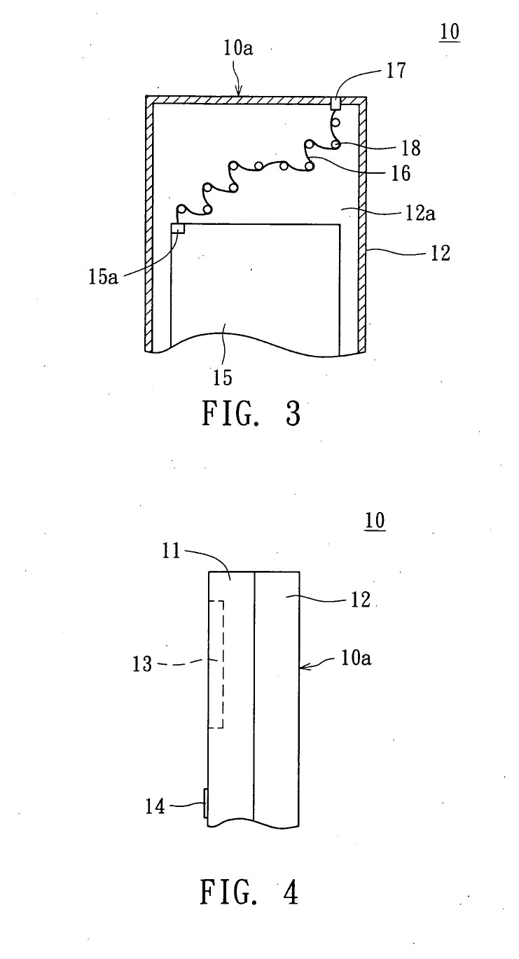

The other part of the guiding bosses 18 which the metal wire is not arranged around can be removed or be retained. As shown in FIG. 3, the other part of the guiding bosses 18 which the metal wire is not arranged around is removed. Only the part of the guiding bosses 18 which the metal wire is arranged around and the first linear antenna 16 are retained.

As shown in FIG. 4, the electronic device 10 of the present embodiment further includes a display unit 13 and a set of buttons 14. The casing 10a further includes a front cover 11. Furthermore, when the other part of the guiding bosses 18 which the metal wire is not arranged around is removed, the front cover 11 and the back cover 12 can be connected to each other to house the first linear antenna 16, the circuit board 15 and part of the guiding bosses 18 in FIG. 3. Alternatively, when the other part of the guiding bosses 18 which the metal wire is not arranged around is retained, the front cover 11 and the back cover 12 can be connected to each other to house the first linear antenna 16, the circuit board 15 and all the guiding bosses 18. The display unit 13 and the set of buttons 14 are disposed on a surface of the front cover 11.

However, anyone who has ordinary skill in the field of the present embodiment of the invention can understand that the invention is not limited thereto. For example, the guiding bosses 18 and the casing 12 can be formed integrally. Furthermore, the guiding bosses 18 include plastic, rubber or polymer. Moreover, the guiding bosses 18 include metal or metal alloy. The linear antennas formed by metal wires include metal or metal alloy with good electrical conductivity, such as brass and galvanized iron. The circuit board 15 described above can include a printed circuit board (PCB) or a flexible circuit board. And the electronic device 10 can be a mobile phone, a personal digital assistant (PDA) or an electronic device utilizing global positioning system (GPS). Although different linear antennas are formed by different metal wires arranged around the guiding bosses along different paths in the present embodiment of the invention, a thin metal film can be used as well for being arranged around the guiding bosses along different paths to form different linear antennas in the present embodiment of the invention.

In the present embodiment of the invention, the thin metal film with the area of 20 mm by 40 mm can be cut into several thin metal strips. Then, the thin metal strips are arranged around the guiding bosses along different paths to form different linear antennas. Afterwards, the linear antenna is electrically connected to the circuit board and the receiver. As a result, in the condition that the total area of the thin metal film is unchanged, the space that the linear antenna of the present embodiment occupies is much less than the space that the conventional antenna module does.

Therefore, the design of the present embodiment that the total area of the linear antenna is the same can easily achieve the requirements described above. And the area can be increased or decreased according to the type, the inner space, the environment or other parameters of the electronic device, for enabling the performance of the electronic device in receiving and transmitting signals to meet the requirements. Moreover, long narrow metal wire or thin metal film is arranged around the guiding bosses to form the linear antenna in the present embodiment of the invention. Therefore, except the necessary guiding bosses, the receiver and the electronic terminal of the circuit board, the space that the linear antenna occupies in the electronic device is quite little. As a result, the space that the linear antenna releases is advantageous to the arrangement of other electronic components. And the appearance of the electronic device can have more variety without considering how to avoid meeting the linear antenna.

Second Embodiment

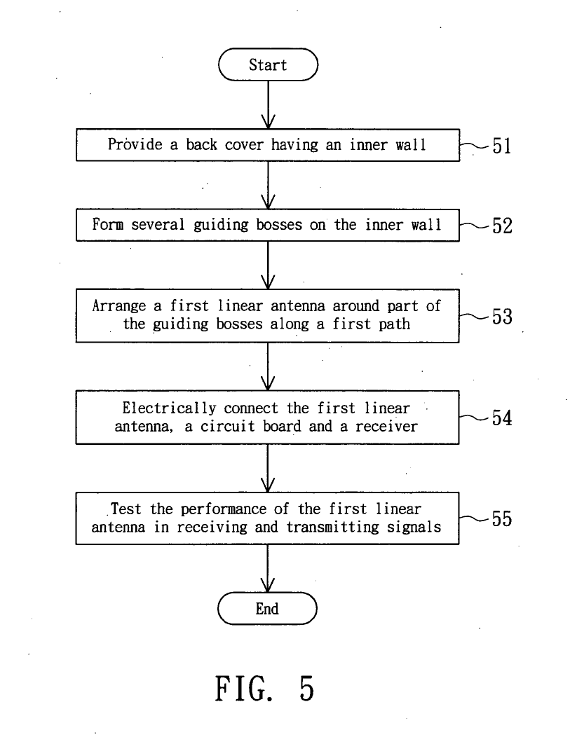

Please referring to FIG. 5, a method for manufacturing a linear antenna of an electronic device according to the second embodiment of the invention is illustrated. Please refer to FIGS. 1˜4 at the same time. In FIG. 5, first, a back cover 12 is provided in the step 51. The back cover 12 has an inner wall 12a. Then, several guiding bosses 18 are formed on the inner wall 12a in step 52. Next, a first linear antenna 16 is arranged around part of the guiding bosses 18 along a first path 19a in step 53. Afterwards, the first linear antenna 16 is electrically connected to a circuit board 15 and a receiver 17 in step 54. Subsequently, the performance of the linear antenna 16 in receiving and transmitting signals is tested in step 55.

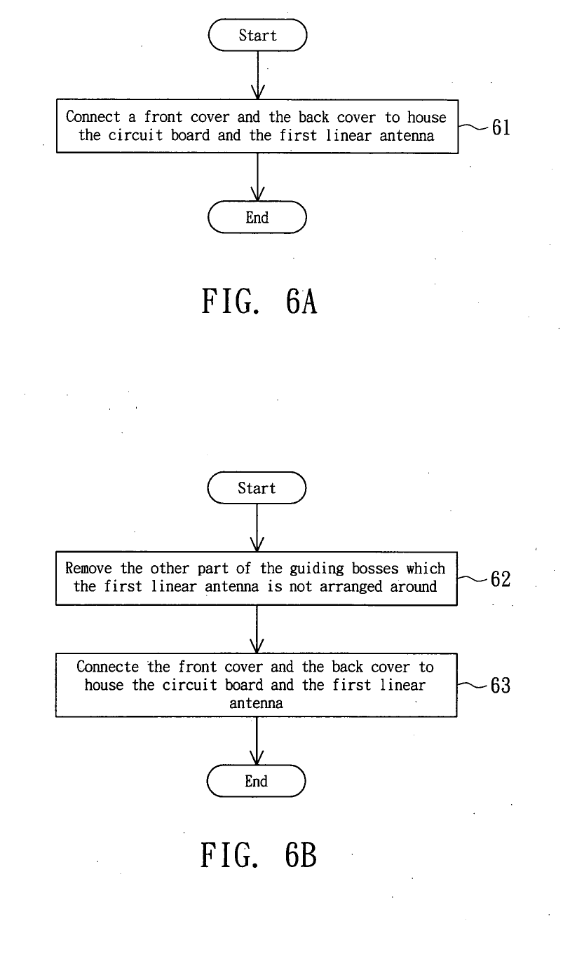

When the first linear antenna 16 passes the performance test, the front cover 11 and the back cover 12 are connected together for housing the circuit board 15, the first linear antenna 16 and all the guiding bosses 18 in step 61 as shown in FIG. 6A. Alternatively, when the first linear antenna 16 passes the performance test, the other part of the guiding bosses 18 which the first linear antenna 16 is not arranged around is removed in step 62 as shown in FIG. 6B. Then, the front cover 11 and the back cover 12 are connected together for housing the circuit board 15, the first linear antenna 16 and part of the guiding bosses 18.

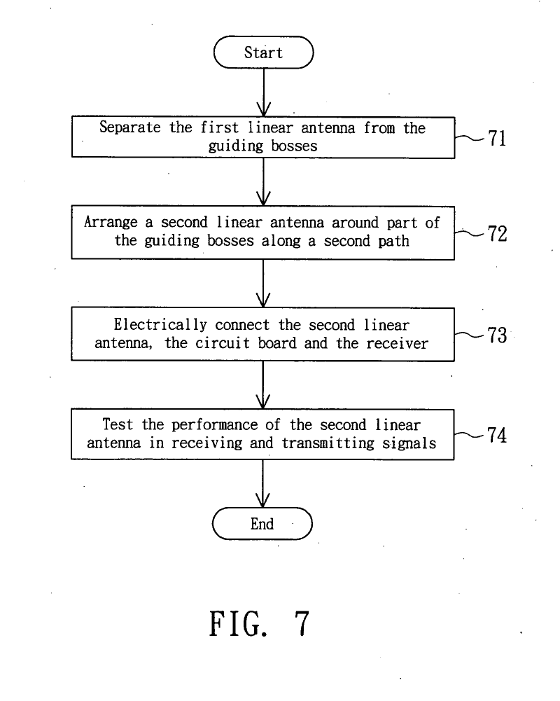

Furthermore, when the first linear antenna 16 does not pass the performance test, the first linear antenna 16 is separated from the guiding bosses 18 in step 71 as shown in FIG. 7. Then, a second linear antenna is arranged around part of the guiding bosses 18 along a second path 19b in step 72. Next, the second linear antenna is electrically connected to the circuit board 15 and the receiver 17 in step 73. Afterwards, the performance of the second linear antenna in receiving and transmitting signals is tested in step 74.

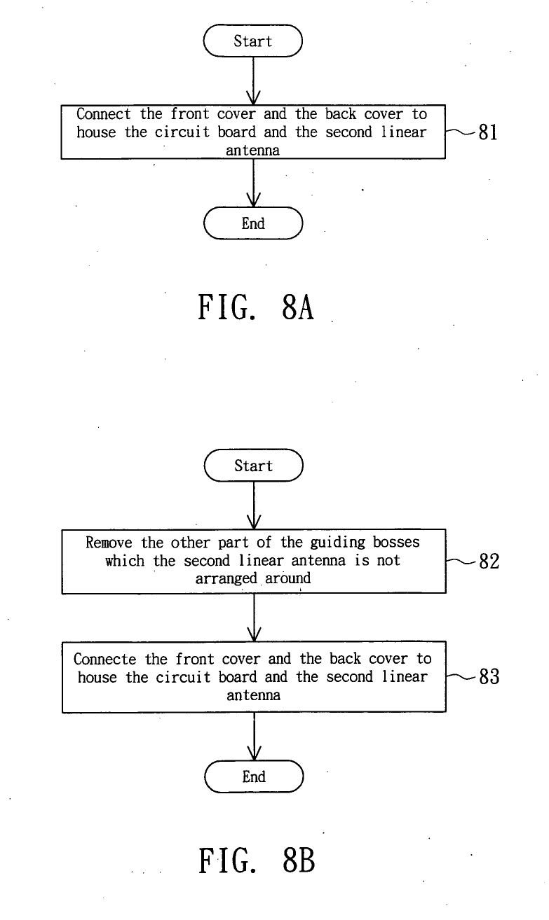

When the second linear antenna passes the performance test, the front cover 11 and the back cover 12 are connected together to house the circuit board 15, the second linear antenna and all the guiding bosses 18 in step 81 as shown in FIG. 8A. Alternatively, when the second linear antenna passes the performance test, the other part of the guiding bosses 18 which the second linear antenna is not arranged around is removed in step 82 as shown in FIG. 8B. Then, the front cover 11 and the back cover 12 are connected together to house the circuit board 15, the second linear antenna and the other part of the guiding bosses 18 in step 83.

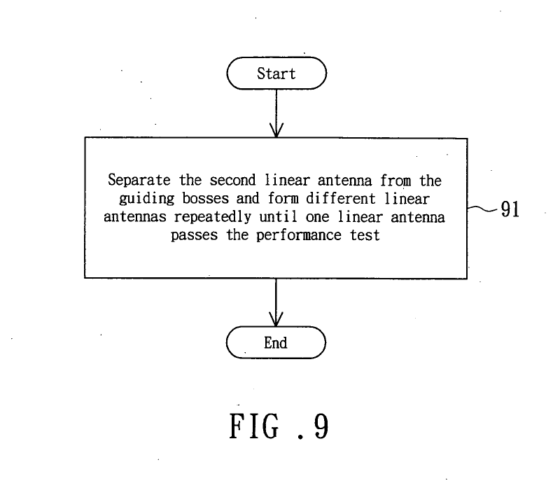

When the second linear antenna does not pass the performance test, the second linear antenna is separated from the guiding bosses 18 in step 91 as shown in FIG. 9. A metal wire in different length is arranged around part of the guiding bosses 18 along a path 19c to form a third linear antenna. Repeat the step of arranging metal wires around part of the guiding bosses along different paths to form different linear antennas. And then the performance of each antenna in receiving and transmitting signals is tested until a linear antenna passes the performance test.

The electronic device and the method for manufacturing linear antenna thereof in the present embodiment of the invention utilize the linear antenna arranged around the guiding bosses. Therefore, the problem that the conventional antenna module needs to be remolded due to poor performance is solved. The cost of the mold is reduced, and the time of manufacturing the antenna is shortened as well. Furthermore, the linear antenna of the present embodiment can reduce the space it occupied in the electronic device, to release more space for other electronic components. The utilization of the inner space of the electronic device is improved enormously. Moreover, because the space that the linear antenna of the present embodiment occupies is less than the space that the conventional linear module does, the appearance of the electronic device can be designed easily.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device, comprising:
a casing having an inner wall;
a plurality of guiding bosses disposed on the inner wall;
a circuit board disposed inside the casing;
a receiver; and
a linear antenna arranged around parts of the guiding bosses along a path, wherein the linear antenna is electrically connected to the circuit board and the receiver respectively.

2. The electronic device according to claim 1, wherein the guiding bosses are disposed on the inner wall in a regular arrangement.

3. The electronic device according to claim 1, wherein the guiding bosses are disposed on the inner wall in an irregular arrangement.

4. The electronic device according to claim 1, wherein the guiding bosses and the casing are formed integrally.

5. The electronic device according to claim 1, wherein the guiding bosses include plastic, rubber or polymer.

6. The electronic device according to claim 1, wherein the guiding bosses include metal or metal alloy.

7. The electronic device according to claim 1, wherein the linear antenna includes brass or galvanized iron.

8. The electronic device according to claim 1, wherein the circuit board includes a printed circuit board (PCB).

9. The electronic device according to claim 1, wherein the casing includes:
a front cover and a back cover detachably connected to each other for housing the linear antenna and the circuit board, wherein the back cover has the inner wall.

10. The electronic device according to claim 1, wherein the other part of the guiding bosses which the linear antenna is not arranged around is removed.

11. The electronic device according to claim 1, being a mobile phone, a personal digital assistant (PDA) or an electronic device utilizing a global positioning system (GPS).

12. A method for manufacturing a linear antenna of an electronic device, comprising: providing a back cover having an inner wall;
forming a plurality of guiding bosses on the inner wall;
arranging a first linear antenna around part of the guiding bosses along a first path;
electrically connecting the first linear antenna respectively to a circuit board and a receiver; and
testing the performance of the first linear antenna in receiving and transmitting signals.

13. The method according to claim 12, further comprising:
connecting a front cover and the back cover to house the circuit board and the first linear antenna when the first linear antenna passes the performance test.

14. The method according to claim 12, further comprising:
removing the other part of the guiding bosses which the first linear antenna is not arranged around when the first linear antenna passes the performance test; and
connecting a front cover and the back cover to house the circuit board and the first linear antenna.

15. The method according to claim 12, further comprising:
separating the first linear antenna from the guiding bosses when the first linear antenna does not pass the performance test;
arranging a second linear antenna around part of the guiding bosses along a second path;
electrically connecting the second linear antenna respectively to the circuit board and the receiver;
testing the performance of the second linear antenna in receiving and transmitting signals;
connecting a front cover and the back cover to house the circuit board and the second linear antenna when the second antenna passes the performance test; and
separating the second linear antenna from the guiding bosses when the second linear antenna does not pass the performance test, and forming different linear antennas repeatedly until one linear antenna passes the performance test.

16. The method according to claim 12, further comprising:
separating the first linear antenna from the guiding bosses when the first linear antenna dose not pass the performance test;
arranging a second linear antenna around part of the guiding bosses along a second path;
electrically connecting the second linear antenna, the circuit board and the receiver;
testing the performance of the second linear antenna in receiving and transmitting signals;
removing the other part of the guiding bosses which the second linear antenna is not arrange around when the second linear antenna passes the performance test, and connecting a front cover and the back cover to house the circuit board and the second linear antenna; and
separating the second linear antenna from the guiding bosses when the second linear antenna does not pass the performance test, and forming different linear antennas repeatedly until one linear antenna passes the performance test.

17. The method according to claim 12, wherein the guiding bosses are disposed on the inner wall in a regular arrangement.

18. The method according to claim 12, wherein the guiding bosses are disposed on the inner wall in an irregular arrangement.

19. The method according to claim 12, wherein the guiding bosses include plastic, rubber or polymer.

20. The method according to claim 12, wherein the guiding bosses include metal or metal alloy.
